(19) United States
(12) Patent Application Publication
(10) Pub. No.: US 2026/0271332 A1
(43) Pub. Date: Sep. 10, 2026

(54) SEMICONDUCTOR DEVICE WITH HIGH-K METAL GATE LAYER AND METHOD FOR PREPARING THE SAME

(71) Applicant: NANYA TECHNOLOGY CORPORATION, NEW TAIPEI CITY (TW)

(72) Inventors: YAN-CHENG JHOU, NEW TAIPEI CITY (TW); CHUNG-PING LIN, NEW TAIPEI CITY (TW)

(21) Appl. No.: 19/206,422

(22) Filed: May 13, 2025

Related U.S. Application Data
(63) Continuation of application No. 19/073,331, filed on Mar. 7, 2025.

(51) Int. Cl. H10D 30/62; H10D 30/01; H10D 64/01; H10D 64/66

(52) U.S. Cl. CPC H10D 30/6217; H10D 30/024; H10D 64/01; H10D 64/667

(57) ABSTRACT

A semiconductor device includes a fin structure disposed over a semiconductor substrate. The semiconductor device also includes a source/drain region disposed in the fin structure. The semiconductor device further includes a gate structure disposed over and extending into the fin structure. The gate structure is disposed adjacent to the source/drain region. The gate structure includes a high-k metal gate layer and a lower gate electrode layer disposed over the high-k metal gate layer.

### CROSS-REFERENCE TO RELATED APPLICATION

This application is a continuation application of U.S. Non-Provisional application Ser. No. 19/073,331 filed Mar. 7, 2025, which is incorporated herein by reference in its entirety.

### TECHNICAL FIELD

The present disclosure relates to a semiconductor device and a method for preparing the same, and more particularly, to a semiconductor device with a high-k metal gate layer and a method for preparing the same.

### DISCUSSION OF THE BACKGROUND

Semiconductor devices are essential for many modern applications. With the advancement of electronic technology, semiconductor devices are becoming smaller in size while providing greater functionality and including greater amounts of integrated circuitry. Due to the miniaturized scale of semiconductor devices, various types and dimensions of semiconductor devices providing different functionalities are integrated and packaged into a single module. Furthermore, numerous manufacturing operations are implemented for integration of various types of semiconductor devices.

However, the manufacturing and integration of semiconductor devices involve many complicated steps and operations. An increase in the complexity of manufacturing and miniaturization of semiconductor devices may cause deficiencies. For example, transistors with reduced channel lengths suffer from short-channel effects, such as increased off-state leakage current. Accordingly, there is a continuous need to improve the manufacturing process of semiconductor devices so that the problems can be addressed.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

In one embodiment of the present disclosure, a semiconductor device is provided. The semiconductor device includes a fin structure disposed over a semiconductor substrate. The semiconductor device also includes a source/drain (S/D) region disposed in the fin structure. The semiconductor device further includes a gate structure disposed over and extending into the fin structure. The gate structure is disposed adjacent to the S/D region. The gate structure includes a high-k metal gate layer and a lower gate electrode layer disposed over the high-k metal gate layer.

In an embodiment, the high-k metal gate layer of the gate structure has a U-shaped profile in the fin structure. In an embodiment, the high-k metal gate layer of the gate structure comprises titanium nitride (TiN), lanthanum (La), aluminum (Al), or a combination thereof. In an embodiment, the gate structure further includes a gate dielectric layer disposed between the fin structure and the high-k metal gate layer. In an embodiment, the gate dielectric layer of the gate structure has a U-shaped profile in the fin structure. In an embodiment, the high-k metal gate layer is separated from the fin structure by the gate dielectric layer.

In an embodiment, the lower gate electrode layer of the gate structure has a lower portion disposed in the fin structure and an upper portion disposed above a top surface of the fin structure. In an embodiment, the lower portion of the lower gate electrode layer is surrounded by the high-k metal gate layer. In an embodiment, a sidewall of the upper portion of the lower gate electrode layer is substantially aligned with a sidewall of the high-k metal gate layer. In an embodiment, the sidewall of the high-k metal gate layer is disposed over the top surface of the fin structure.

In an embodiment, the semiconductor device further includes a spacer structure disposed on a sidewall of the gate structure, wherein the spacer structure is in direct contact with the high-k metal gate layer of the gate structure. In an embodiment, he spacer structure is in direct contact with the lower gate electrode layer of the gate structure. In an embodiment, the gate structure further includes an upper gate electrode layer disposed over the lower gate electrode layer, and a cap layer disposed over the upper gate electrode layer, wherein the spacer structure is in direct contact with the upper gate electrode layer and the cap layer. In an embodiment, the semiconductor device further includes an isolation structure disposed over the semiconductor substrate, wherein the fin structure protrudes from the isolation structure, and the gate structure extends over the isolation structure.

In another embodiment of the present disclosure, a semiconductor device is provided. The semiconductor device includes a first fin structure disposed over a semiconductor substrate and extending along a direction. The semiconductor device also includes a source/drain (S/D) region disposed in the first fin structure. The semiconductor device further includes a gate structure disposed across the first fin structure and adjacent to the S/D region. The gate structure includes a high-k metal gate layer, and a lower gate electrode layer disposed over the high-k metal gate layer. A top surface of the first fin structure is higher than a bottom surface of the gate structure in a cross section along the direction of the first fin structure.

In an embodiment, the top surface of the first fin structure is higher than a bottom surface of the high-k metal gate layer of the gate structure in the cross section along the direction of the first fin structure. In an embodiment, the top surface of the first fin structure is higher than a bottom surface of the lower gate electrode layer of the gate structure in the cross section along the direction of the first fin structure. In an embodiment, a top surface of the lower gate electrode layer of the gate structure is higher than the top surface of the first fin structure in the cross section along the direction of the first fin structure. In an embodiment, a portion of the first fin structure is sandwiched between the gate structure and the S/D region. In an embodiment, the high-k metal gate layer of the gate structure has a U-shaped profile in the cross section along the direction of the first fin structure.

In an embodiment, the U-shaped profile of the high-k metal gate layer of the gate structure is in the first fin structure. In an embodiment, the gate structure further includes a gate dielectric layer disposed between the first fin structure and the high-k metal gate layer. In an embodiment, the high-k metal gate layer is surrounded by the gate dielectric layer in the cross section along the direction of the first fin structure. In an embodiment, the semiconductor device further includes a spacer structure disposed over the top surface of the first fin structure, wherein a sidewall of the gate structure is covered by the spacer structure. In an embodiment, the spacer structure is in direct contact with the high-k metal gate layer and the lower gate electrode layer of the gate structure.

In an embodiment, the gate structure further includes an upper gate electrode layer disposed over the lower gate electrode layer, and a cap layer disposed over the upper gate electrode layer, wherein the spacer structure is in direct contact with the upper gate electrode layer and the cap layer. In an embodiment, the semiconductor device further includes a second fin structure disposed over the semiconductor substrate and extending along the direction of the first fin structure, wherein the gate structure extends across the second fin structure. In an embodiment, the semiconductor device further includes an isolation structure disposed over the semiconductor substrate, wherein the first fin structure and the second fin structure protrude from the isolation structure. In an embodiment, the high-k metal gate layer of the gate structure extends over a top surface of the isolation structure between the first fin structure and the second fin structure.

In yet another embodiment of the present disclosure, a method for preparing a semiconductor device is provided. The method includes forming a first fin structure over a semiconductor substrate and partially removing the first fin structure to form a recess. The method also includes depositing a high-k metal gate layer lining and partially filling the recess and depositing a lower gate electrode layer over the high-k metal gate layer. A remaining portion of the recess is filled by the lower gate electrode layer. The method further includes performing an etching process on the high-k metal gate layer and the lower gate electrode layer to form a gate structure and forming a source/drain (S/D) region in the first fin structure and adjacent to the gate structure.

In an embodiment, the method further includes forming an isolation structure over the semiconductor substrate, wherein the first fin structure protrudes from the isolation structure, and a bottom surface of the recess is higher than a top surface of the isolation structure. In an embodiment, the method further includes forming a second fin structure over the semiconductor substrate, wherein the second fin structure extends parallel to the first fin structure, and the second fin structure is partially removed to form the recess. In an embodiment, the method further includes depositing a gate dielectric layer covering a sidewall and a bottom surface of the recess in the first fin structure before the high-k metal gate layer is formed.

In an embodiment, the gate dielectric layer is partially removed by the etching process to form the gate structure, such that a sidewall of the gate dielectric layer is substantially aligned with a sidewall of the high-k metal gate layer. In an embodiment, the high-k metal gate layer is separated from the sidewall and the bottom surface of the recess in the first fin structure by the gate dielectric layer. In an embodiment, before performing the etching process, the method further includes depositing an upper gate electrode layer over the lower gate electrode layer and depositing a cap layer over the upper gate electrode layer.

In an embodiment, the method further includes forming a patterned mask over the cap layer, wherein the gate structure is formed by performing the etching process on the gate dielectric layer, the high-k metal gate layer, the upper gate electrode layer and the cap layer using the patterned mask as a mask. In an embodiment, a top surface of the first fin structure is exposed after the etching process is performed. In an embodiment, the method further includes forming a spacer structure covering a sidewall of the gate structure, wherein the spacer structure is in direct contact with the top surface of the first fin structure. In an embodiment, the S/D region is formed after the spacer structure is formed.

Embodiments of a semiconductor device with a high-k metal gate layer and method for preparing the same are provided in the disclosure. In some embodiments, the semiconductor device includes a gate structure disposed over and extending into a fin structure, and the gate structure includes a high-k metal gate layer. As a result, the gate control ability is increased, the leakage current is reduced or eliminated, thereby improving the overall performance of the semiconductory device.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a top view illustrating a semiconductor device, in accordance with some embodiments.

FIG. 2 is a cross-sectional view illustrating the semiconductor device along the line A-A′ of FIG. 1, in accordance with some embodiments.

FIG. 3 is a cross-sectional view illustrating the semiconductor device along the line B-B′ of FIG. 1, in accordance with some embodiments.

FIG. 4 is a flow diagram illustrating a method for preparing a semiconductor device, in accordance with some embodiments.

FIG. 5 is a top view illustrating an intermediate stage in the formation of a patterned mask over a semiconductor substrate in the preparation of the semiconductor device, in accordance with some embodiments.

FIG. 6 is a cross-sectional view illustrating an intermediate stage in the preparation of the semiconductor device along the line A-A′ of FIG. 5, in accordance with some embodiments.

FIG. 7 Is a cross-sectional view illustrating an intermediate stage following FIG. 6 in the preparation of the semiconductor device, along the line A-A′ of FIG. 5, in accordance with some embodiments.

FIG. 8 is a cross-sectional view illustrating an intermediate stage following FIG. 7 in the preparation of the semiconductor device, along the line A-A′ of FIG. 5, in accordance with some embodiments.

FIG. 9 is a top view illustrating an intermediate stage in the formation of a patterned mask over fin structures in the preparation of the semiconductor device, in accordance with some embodiments.

FIG. 10 is a cross-sectional view illustrating an intermediate stage in the preparation of the semiconductor device along the line A-A′ of FIG. 9, in accordance with some embodiments.

FIG. 11 is a cross-sectional view illustrating an intermediate stage in the preparation of the semiconductor device along the line B-B′ of FIG. 9, in accordance with some embodiments.

FIG. 12 is a cross-sectional view illustrating an intermediate stage following FIG. 10 in the preparation of the semiconductor device, along the line A-A′ of FIG. 9, in accordance with some embodiments.

FIG. 13 is a cross-sectional view illustrating an intermediate stage following FIG. 11 in the preparation of the semiconductor device, along the line B-B′ of FIG. 9, in accordance with some embodiments.

FIG. 14 is a cross-sectional view illustrating an intermediate stage following FIG. 12 in the preparation of the semiconductor device, along the line A-A′ of FIG. 9, in accordance with some embodiments.

FIG. 15 is a cross-sectional view illustrating an intermediate stage following FIG. 13 in the preparation of the semiconductor device, along the line B-B′ of FIG. 9, in accordance with some embodiments.

FIG. 16 is a cross-sectional view illustrating an intermediate stage following FIG. 14 in the preparation of the semiconductor device, along the line A-A′ of FIG. 9, in accordance with some embodiments.

FIG. 17 is a cross-sectional view illustrating an intermediate stage following FIG. 15 in the preparation of the semiconductor device, along the line B-B′ of FIG. 9, in accordance with some embodiments.

FIG. 18 is a cross-sectional view illustrating an intermediate stage following FIG. 16 in the preparation of the semiconductor device, along the line A-A′ of FIG. 9, in accordance with some embodiments.

FIG. 19 is a cross-sectional view illustrating an intermediate stage following FIG. 17 in the preparation of the semiconductor device, along the line B-B′ of FIG. 9, in accordance with some embodiments.

FIG. 20 is a top view illustrating an intermediate stage in the formation of a patterned mask over a cap layer in the preparation of the semiconductor device, in accordance with some embodiments.

FIG. 21 is a cross-sectional view illustrating an intermediate stage in the preparation of the semiconductor device along the line A-A′ of FIG. 20, in accordance with some embodiments.

FIG. 22 is a cross-sectional view illustrating an intermediate stage in the preparation of the semiconductor device along the line B-B′ of FIG. 20, in accordance with some embodiments.

FIG. 23 is a cross-sectional view illustrating an intermediate stage following FIG. 21 in the preparation of the semiconductor device, along the line A-A′ of FIG. 20, in accordance with some embodiments.

FIG. 24 is a top view illustrating an intermediate stage in the formation of a spacer structure on sidewalls of a gate structure in the preparation of the semiconductor device, in accordance with some embodiments.

FIG. 25 is a cross-sectional view illustrating an intermediate stage in the preparation of the semiconductor device along the line A-A′ of FIG. 24, in accordance with some embodiments.

FIG. 26 is a top view illustrating an intermediate stage in the formation of source/drain regions in the fin structures in the preparation of the semiconductor device, in accordance with some embodiments.

FIG. 27 is a cross-sectional view illustrating an intermediate stage in the preparation of the semiconductor device along the line A-A′ of FIG. 26, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

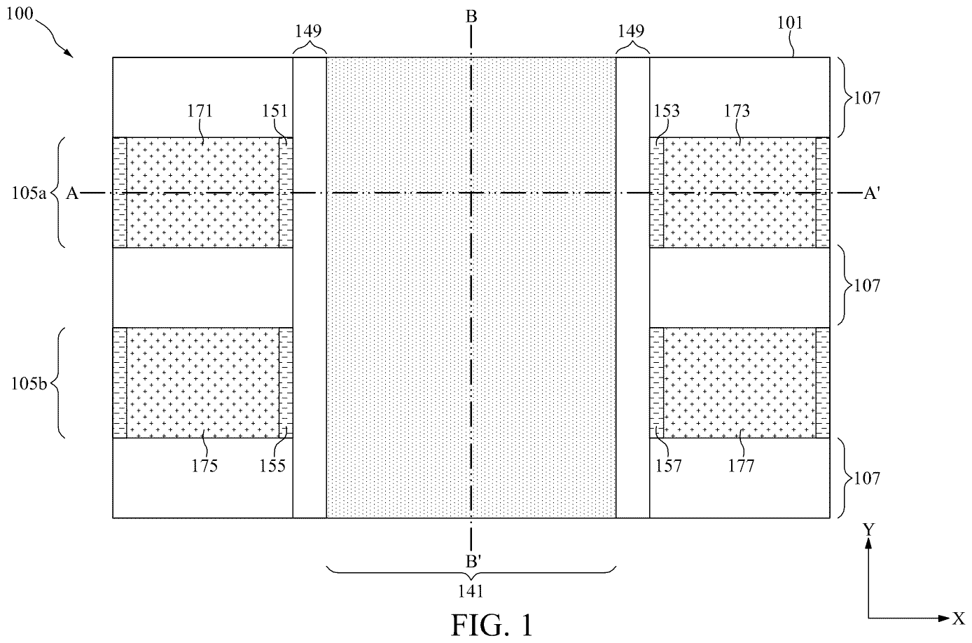

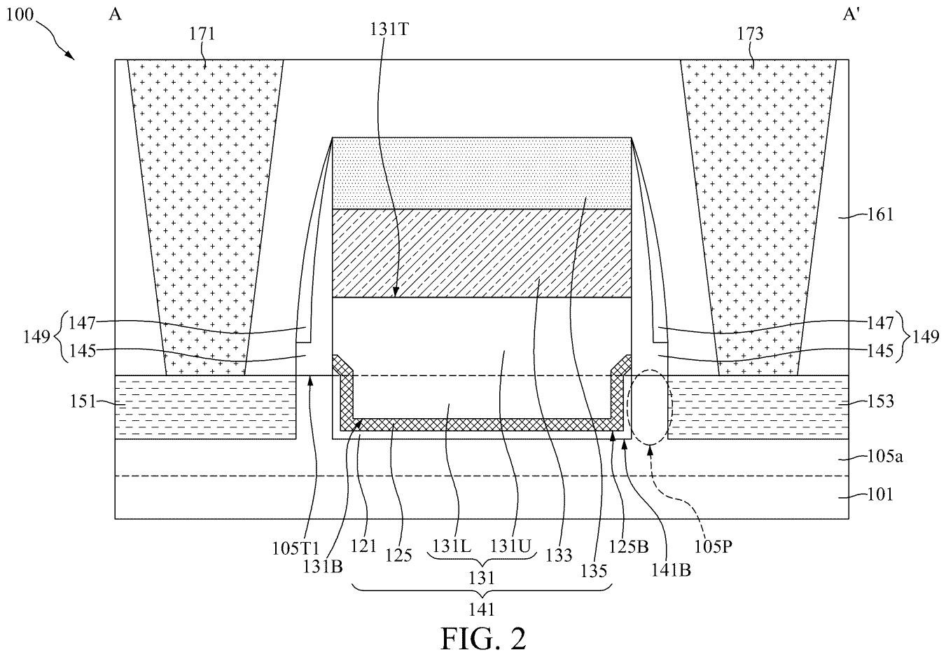

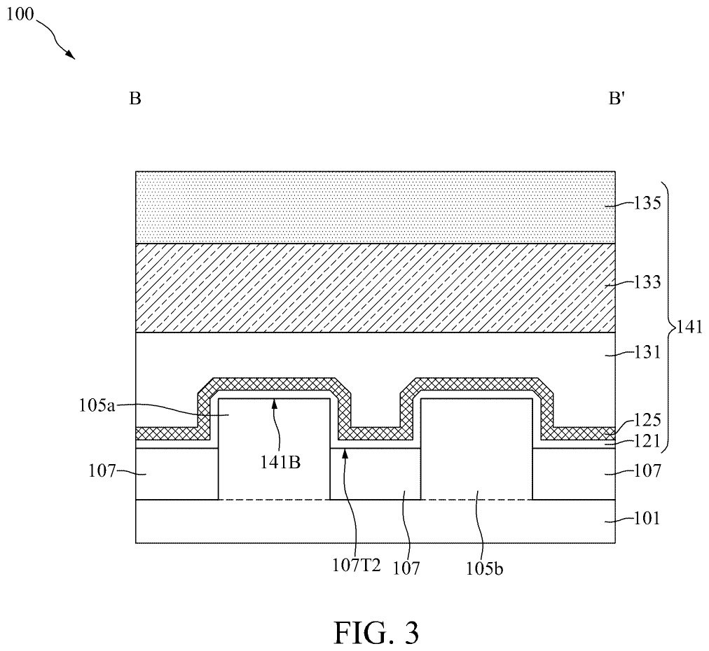

FIG. 1 is a top view illustrating a semiconductor device 100, FIG. 2 is a cross-sectional view illustrating the semiconductor device 100 along the line A-A′ of FIG. 1, and FIG. 3 is a cross-sectional view illustrating the semiconductor device 100 along the line B-B′ of FIG. 1, in accordance with some embodiments.

As shown in FIGS. 1 to 3, the semiconductor device 100 includes a semiconductor substrate 101 and a plurality of fin structures 105a and 105b (also referred to as saddle fin structures) disposed over the semiconductor substrate 101, in accordance with some embodiments. In some embodiments, the fin structures 105a and 105b extend along the same lengthwise direction. For example, as shown in FIG. 1, the fin structures 105a and 105b extend along the X-direction.

In some embodiments, the fin structure 105a is parallel to and spaced apart from the fin structure 105b. Noted that the dashed lines indicating the locations of the fin structures 105a and 105b are used to clarify the disclosure. No obvious interfaces exist between the fin structures 105a, 105b and the semiconductor substrate 101.

The semiconductor device 100 also includes an isolation structure 107 disposed over the semiconductor substrate 101. In some embodiments, the fin structures 105a and 105b protrude from the isolation structure 107. For example, as shown in FIG. 3, the fin structures 105a and 105b protrude from the top surface 107T2 of the isolation structure 107. In some embodiments, the fin structure 105a is separated from the fin structure 105b by the isolation structure 103.

Moreover, the semiconductor device 100 includes a gate structure 141 disposed over and extending into the fin structures 105a and 105b. In some embodiments, the gate structure 141 is disposed across the fin structures 105a and 105b. In some embodiments, the gate structure 141 extends along a lengthwise direction different from the lengthwise direction of the fin structures 105a and 105b. For example, as shown in FIG. 1, the gate structure 141 extends along the Y-direction.

In some embodiments, the gate structure 141 extends into the fin structure 105a, such that a top surface 105T1 of the fin structure 105a is higher than a bottom surface 141B of the gate structure 141 (also referred to as a bottom surface of the gate dielectric layer 121 of the gate structure 141) in the cross section along the line A-A′ of FIG. 1 (i.e., the lengthwise direction of the fin structure 105a). In some embodiments, as shown in FIG. 3, the bottom surfaces of the gate structure 141 over the fin structures 105a and 105b (i.e., the bottom surface 141B) is higher than a top surface 107T2 of the isolation structure 107. In some embodiments, the gate structure 141 extends to cover a portion of the top surface 107T2 of the isolation structure 107 between the fin structures 105a and 105b, as shown in FIG. 3.

In some embodiments, the gate structure 141 includes a gate dielectric layer 121, a high-k metal gate layer 125 disposed over the gate dielectric layer 121, a lower gate electrode layer 131 disposed over the high-k metal gate layer 125, an upper gate electrode layer 133 disposed over the lower gate electrode layer 131, and a cap layer 135 disposed over the upper gate electrode layer 133. In some embodiments, both the gate dielectric layer 121 and the high-k metal gate layer 125 have U-shaped profiles in the fin structure 105a. In some embodiments, the high-k metal gate layer 125 is surrounded by the gate dielectric layer 121 in the cross-section along the line A-A′ of FIG. 1 (i.e., FIG. 2). In some embodiments, the high-k metal gate layer 125 is separated from the fin structures 105a and 105b by the gate dielectric layer 121. In some embodiments, as shown in FIG. 2, the top surface 105T1 of the fin structure 105a is higher than a bottom surface 125B of the high-k metal gate layer 125 of the gate structure 141.

In some embodiments, the lower gate electrode layer 131 has a lower portion 131L in the fin structure 105a and an upper portion 131U disposed above the top surface 105T1 of the fin structure 105a. Noted that the dashed line indicating the boundary between the lower portion 131L and the upper portion 131U of the lower gate electrode layer 131 is used to clarify the disclosure. No obvious interface exists between the lower portion 131L and the upper portion 131U of the lower gate electrode layer 131.

In some embodiments, the lower portion 131L of the lower gate electrode layer 131 is surrounded by the high-k metal gate layer 125 in the cross-section along the line A-A′ of FIG. 1 (i.e., FIG. 2). In some embodiments, as shown in FIG. 2, the top surface 105T1 of the fin structure 105a is higher than a bottom surface 131B of the lower portion 131L of the lower gate electrode layer 131 of the gate structure 141. In some embodiments, as shown in FIG. 2, the top surface 131T of the upper portion 131U of the lower gate electrode layer 131 of the gate structure 141 is higher than the top surface 105T1 of the fin structure 105a.

In some embodiments, the upper gate electrode layer 133 and the cap layer 135 of the gate structure 141 are disposed over the fin structure 105a. In some embodiments, opposite sidewalls of the gate dielectric layer 121, the high-k metal gate layer 125, the upper portion 131U of the lower gate electrode layer 131, the upper gate electrode layer 133 and the cap layer 135 are substantially aligned, which also referred to as opposite sidewalls of the gate structure 141. Within the context of this disclosure, the word “substantially” means preferably at least 90%, more preferably 95%, even more preferably 98%, and most preferably 99%.

In addition, the semiconductor device 100 includes a spacer structure 149 disposed on the opposite sidewalls of the gate structure 141. In some embodiments, the spacer structure 149 is disposed over the fin structure 105a. In some embodiments, the spacer structure 149 is in direct contact with the top surfaces of the fin structures 105a and 105b (e.g., the top surface 105T1 of the fin structure 105a). In some embodiments, the spacer structure 149 is in direct contact with the gate dielectric layer 121, the high-k metal gate layer 125, the upper portion 131U of the lower gate electrode layer 131, the upper gate electrode layer 133, and the cap layer 135.

In some embodiments, the spacer structure 149 includes a first spacer layer 145 and a second spacer layer 147 disposed over the first spacer layer 145. In some embodiments, the first spacer layer 145 has an L-shaped profile in the cross-sectional view of FIG. 2. In some embodiments, the second spacer layer 147 is separated from the gate structure 141 by the first spacer layer 145.

In some embodiments, the semiconductor device 100 includes a plurality of source/drain (S/D) regions 151, 153, 155 and 157 in the fin structures 105a and 105b. In some embodiments, the S/D regions 151, 153, 155 and 157 are disposed adjacent to the gate structure 141. In some embodiments, the S/D regions 151, 153, 155 and 157 are disposed adjacent to the spacer structure 149. In some embodiments, the S/D regions 151 and 153 are disposed in the fin structure 105a and at opposite sides of the gate structure 141, and the S/D regions 155 and 157 are disposed in the fin structure 105b and at opposite sides of the gate structure 141.

In some embodiments, since the gate structure 141 extends into the fin structure 105a, the fin structure 105a has a portion sandwiched between the gate structure 141 and the S/D region 151, and another portion sandwiched between the gate structure 141 and the S/D region 153. For example, a portion 105P of the fin structure 105a is sandwiched between the gate structure 141 and the S/D region 153, as shown in FIG. 2. Noted that the dashed line indicating the location of the portion 105P is used to clarify the disclosure.

Furthermore, the semiconductor device 100 includes a dielectric layer 161 covering the gate structure 141, and a plurality of conductive contacts 171, 173, 175 and 177 penetrating through the dielectric layer 161. In some embodiments, the conductive contacts 171 and 173 are disposed over the fin structure 105a and at opposite sides of the gate structure 141. In some embodiments, the conductive contacts 171 and 173 penetrate through the dielectric layer 161 to contact the S/D regions 151 and 153, respectively.

In some embodiments, the conductive contacts 175 and 177 penetrate through the dielectric layer 161 to contact the S/D regions 155 and 157, respectively. The conductive contacts 171, 173, 175 and 177 may help to electrically connect the S/D regions 151, 153, 155 and 157, respectively. It should be noted that the dielectric layer 161 is omitted from the top view of FIG. 1 for clarity.

Embodiments of the semiconductor device 100 with the high-k metal gate layer 125 and method for preparing the same are provided in the disclosure. In some embodiments, the semiconductor device 100 includes the gate structure 141 disposed over and extending into the fin structures 105a and 105b. Since the gate structure 141 includes the high-k metal gate layer 125, and the high-k metal gate layer 125 is disposed in a recess in the fin structure 105a, the gate control ability is increased, and the leakage current is reduced or eliminated. As a result, the overall performance of the semiconductor device 100 can be significantly improved.

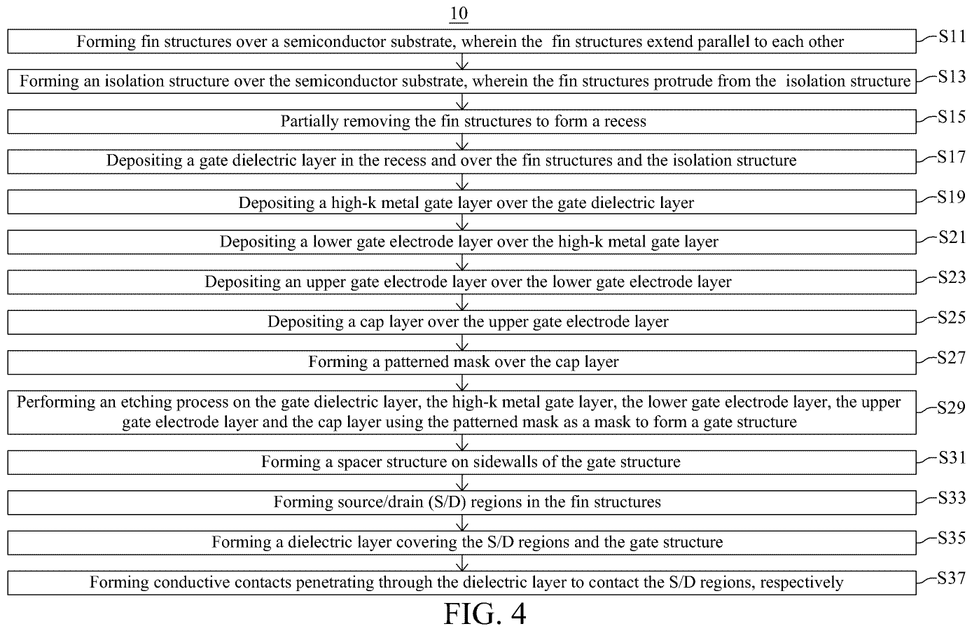

FIG. 4 is a flow diagram illustrating a method 10 for preparing the semiconductor device 100, and the method 10 includes steps S11, S13, S15, S17, S19, S21, S23, S25, S27, S29, S31, S33, S35 and S37, in accordance with some embodiments. The steps S11 to S37 of FIG. 4 are elaborated in connection with the following figures.

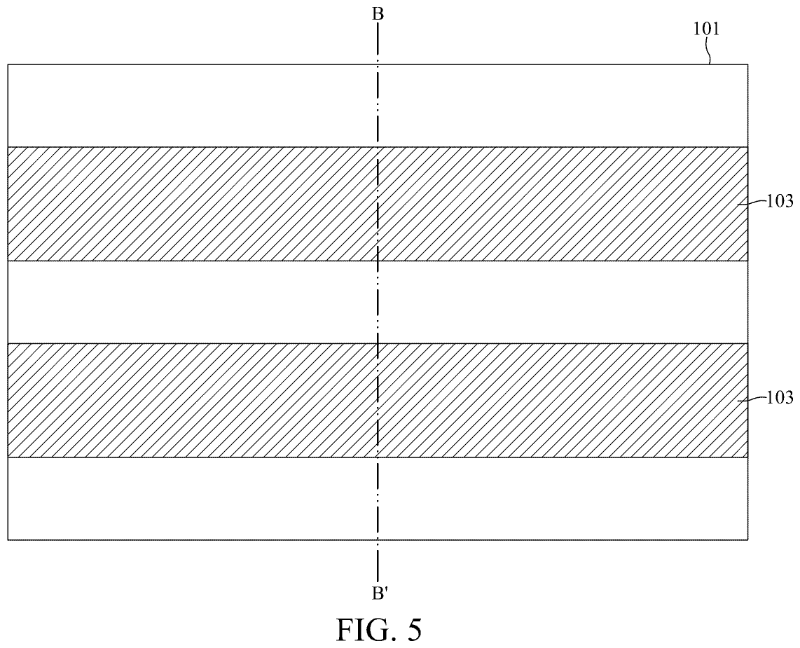

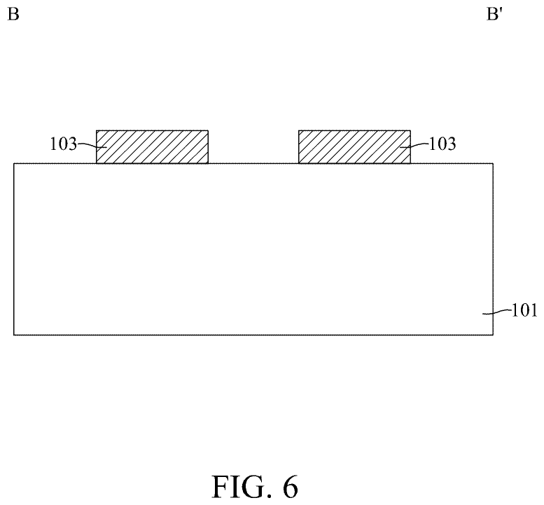

FIG. 5 is a top view illustrating an intermediate stage in the preparation of the semiconductor device 100, and FIG. 6 is a cross-sectional view along the line A-A′ of FIG. 5, in accordance with some embodiments.

As shown in FIGS. 5 and 6, a semiconductor substrate 101 is provided, and a patterned mask 103 is formed over the semiconductor substrate 101, in accordance with some embodiments. The semiconductor substrate 101 may be a semiconductor wafer such as a silicon wafer. Alternatively or additionally, the semiconductor substrate 101 may include elementary semiconductor materials, compound semiconductor materials, and/or alloy semiconductor materials. Examples of the elementary semiconductor materials may include, but are not limited to, crystal silicon, polycrystalline silicon, amorphous silicon, germanium, and/or diamond. Examples of the compound semiconductor materials may include, but are not limited to, silicon carbide, gallium arsenic, gallium phosphide, indium phosphide, indium arsenide, and/or indium antimonide. Examples of the alloy semiconductor materials may include, but are not limited to, SiGe, GaAsP, AlInAs, AlGaAs, GaInAs, GaInP, and/or GaInAsP.

In some embodiments, the semiconductor substrate 101 includes an epitaxial layer. For example, the semiconductor substrate 101 has an epitaxial layer overlying a bulk semiconductor. In some embodiments, the semiconductor substrate 101 is a semiconductor-on-insulator substrate which may include a substrate, a buried oxide layer over the substrate, and a semiconductor layer over the buried oxide layer, such as a silicon-on-insulator (SOI) substrate, a silicon germanium-on-insulator (SGOI) substrate, or a germanium-on-insulator (GOI) substrate. Semiconductor-on-insulator substrates can be fabricated using separation by implantation of oxygen (SIMOX), wafer bonding, and/or other suitable methods. In some embodiments, the patterned mask 103 covers the regions of the semiconductor substrate 101 where fin structures are to be formed.

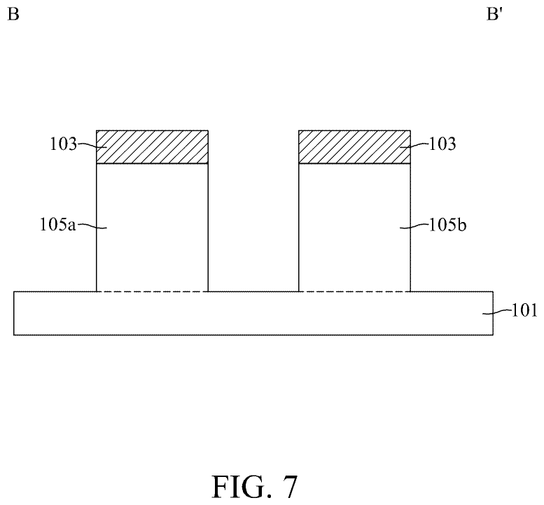

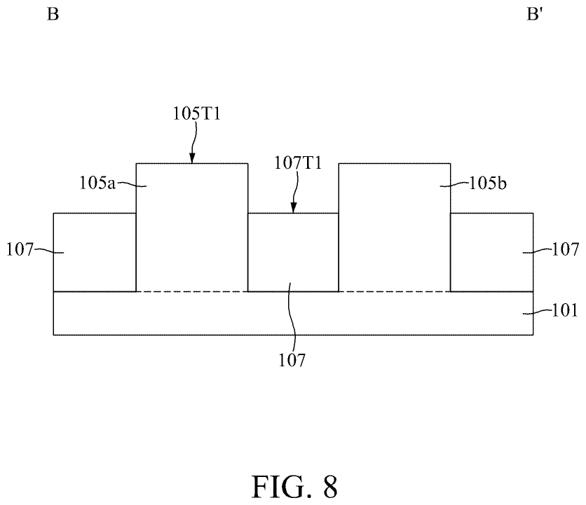

FIGS. 7 and 8 are cross-sectional views illustrating intermediate stages following FIG. 6 in the preparation of the semiconductor device 100, along the line A-A′ of FIG. 5, in accordance with some embodiments.

As shown in FIG. 7, an etching process is performed on the semiconductor substrate 101 using the patterned mask 103 as an etching mask, in accordance with some embodiments. In some embodiments, after the etching process is performed, a plurality of fin structures 105a and 105b are formed over the semiconductor substrate 101. The etching process may be a dry etching process or a wet etching process.

In some embodiments, the fin structures 105a and 105b are formed by a dry etching process using a fluorine-based etchant gas, such as SF6, CxFy, NF3, or a combination thereof. The etching process may be a time-controlled etching process and continue until the fin structures 105a and 105b reach a predetermined height.

In some embodiments, the fin structures 105a and 105b extend parallel to each other in the top view. Although only two fin structures 105a and 105b are illustrated, embodiments may include any number of fin structures (e.g., more than two) over the semiconductor substrate 101. The respective step is illustrated as the step S11 in the method 10 shown in FIG. 4.

Next, an isolation structure 107 is formed over the semiconductor substrate 101, as shown in FIG. 8 in accordance with some embodiments. In some embodiments, the fin structures 105a and 105b protrude from the isolation structure 107. In some embodiments, the top surfaces of the fin structures 105a and 105b (e.g., the top surface 105T1) are higher than the top surface 107T1 of the isolation structure 107. The respective step is illustrated as the step S13 in the method 10 shown in FIG. 4.

In some embodiments, the formation of the isolation structure 107 includes depositing an insulating layer (not shown) over the semiconductor substrate 101 to cover the fin structures 105a and 105b, followed by partially removing the insulating layer by an etching process. In some embodiments, the insulating layer includes silicon oxide, silicon nitride, silicon oxynitride, fluoride-doped silicate glass (FSG), or other low-k dielectric materials. In some embodiments, the insulating layer is deposited by a chemical vapor deposition (CVD) process, a physical vapor deposition (PVD) process, an atomic layer deposition (ALD) process, a spin-on coating process, or another suitable deposition processes. In some embodiments, the insulating layer is partially removed by a wet etching process or a dry etching process.

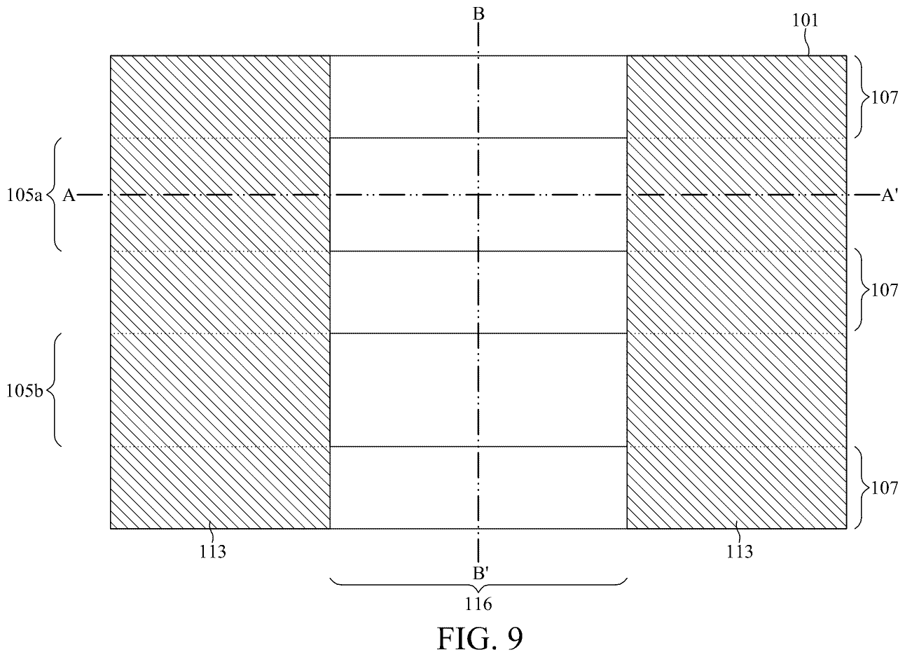

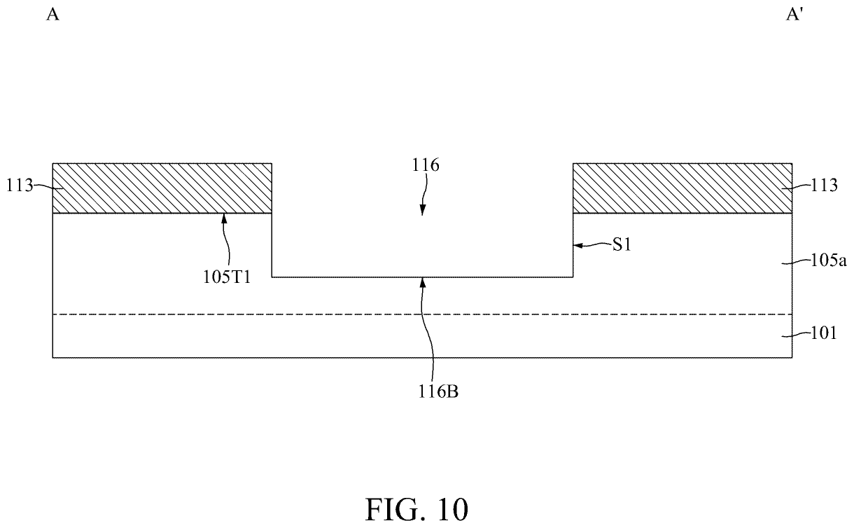

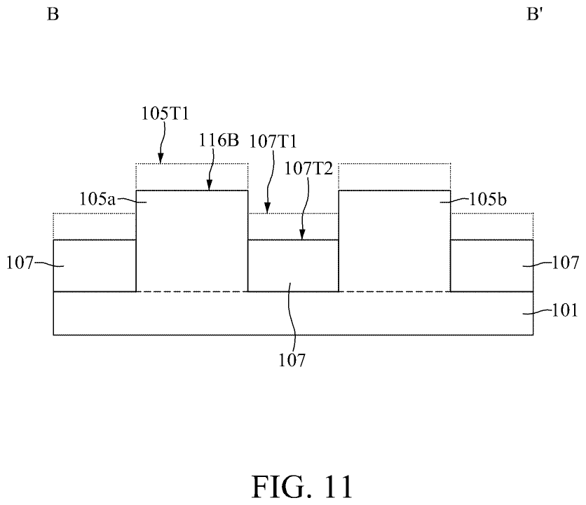

FIG. 9 is a top view illustrating an intermediate stage in the preparation of the semiconductor device 100, FIG. 10 is a cross-sectional view along the line A-A′ of FIG. 9, and FIG. 11 is a cross-sectional view along the line B-B′ of FIG. 9, in accordance with some embodiments.

As shown in FIGS. 9 to 11, a patterned mask 113 is formed over the structure of FIG. 8, and an etching process is performed using the patterned mask 113 as a mask, such that a recess 116 is formed across the fin structures 105a and 105b, in accordance with some embodiments. In some embodiments, the patterned mask 113 exposes the region where a gate structure will be formed. In some embodiments, the portions of the fin structures 105a, 105b and the portions of the isolation structure 107 exposed by the patterned mask 113 are partially removed to form the recess 116. The respective step is illustrated as the step S15 in the method 10 shown in FIG. 4.

In some embodiments, the top surface of the fin structures 105a, 105b covered by the patterned mask 113 (e.g., the top surface 105T1) are higher than the bottom surface 116B of the recess 116 in the fin structures. In some embodiments, a sidewall S1 of the recess 116 is exposed in the fin structure 105a after the etching process is performed. In some embodiments, the isolation structure 107 is partially removed, such that a top surface 107T2 of the isolation structure 107 after the etching process is performed is lower than a top surface 107T1 of the isolation structure 107 before the etching process is performed. In some embodiments, the bottom surface 116B of the recess 116 is higher than the top surface 107T2 of the isolation structure 107 after the etching process is performed.

In some embodiments, the etching process used to form the recess 116 includes a wet etching process, a dry etching process, or a combination thereof. After the recess 116 is formed, the patterned mask 113 may be removed. In some embodiments, the patterned mask 113 is removed by a stripping process, an ashing process, an etching process, or another suitable process.

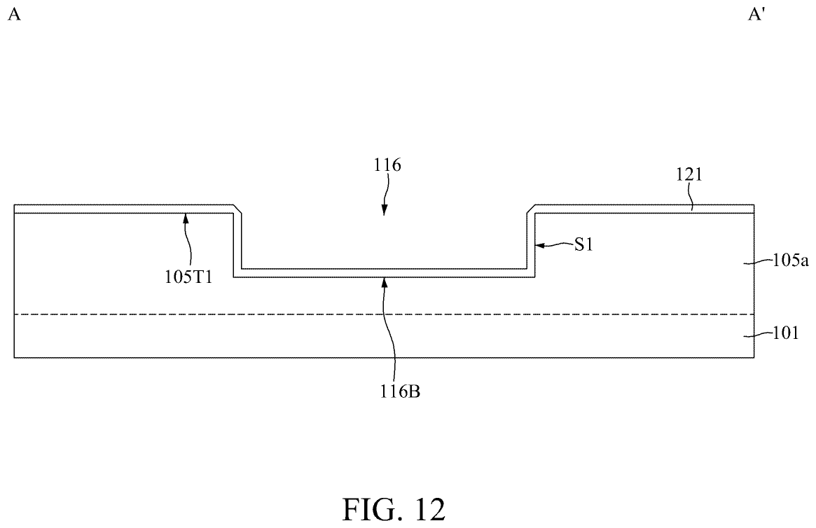

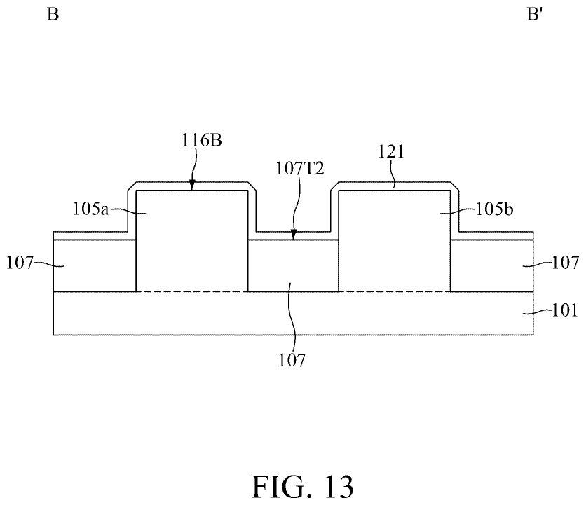

FIGS. 12 to 19 are cross-sectional views illustrating intermediate stages following FIGS. 9 to 11 in the preparation of the semiconductor device 100, FIGS. 12, 14, 16 and 18 are taken along the line A-A′ of FIG. 9, and FIGS. 13, 15, 17 and 19 are taken along the line B-B′ of FIG. 9, in accordance with some embodiments.

After the recess 116 is formed, a gate dielectric layer 121 is conformally deposited over the fin structures 105a, 105b and the isolation structure 107, as shown in FIGS. 12 and 13 in accordance with some embodiments. In some embodiments, the gate dielectric layer 121 covers the top surfaces of the fin structures 105a, 105b (e.g., the top surface 105T1), the bottom surface 116B and the sidewall S1 of the recess 116, and the top surface 107T2 of the isolation structure 107. The respective step is illustrated as the step S17 in the method 10 shown in FIG. 4.

In some embodiments, the gate dielectric layer 121 includes a dielectric material, such as silicon oxide, silicon nitride, silicon oxynitride, a high-k dielectric material, another suitable dielectric material, or a combination thereof. In some embodiments, the gate dielectric layer 121 is deposited by a CVD process, a PVD process, an ALD process, a spin-on coating process, or another suitable deposition process.

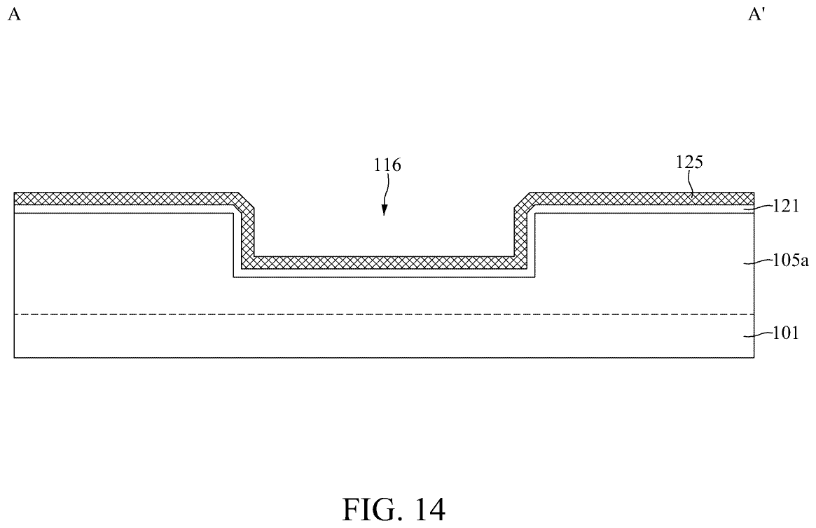

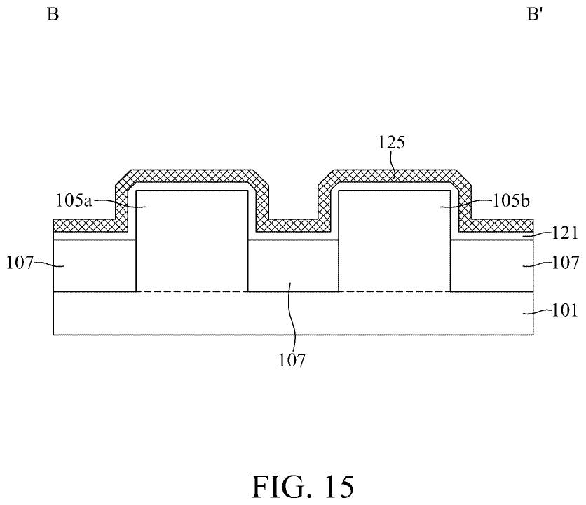

Subsequently, a high-k metal gate layer 125 is conformally deposited over the gate dielectric layer 121, as shown in FIGS. 14 and 15 in accordance with some embodiments. In some embodiments, the high-k metal gate layer 125 extends to line the recess 116. In some embodiments, a material of the high-k metal gate layer 125 is different from a material of the gate dielectric layer 121. The respective step is illustrated as the step S19 in the method 10 shown in FIG. 4.

In some embodiments, the high-k metal gate layer 125 includes titanium nitride (TiN), lanthanum (La), aluminum (Al), or a combination thereof. The materials of the high-k metal gate layer 125 are selected depending on the conductivity type of the semiconductor device 100. For example, if the semiconductor device 100 is an n-channel metal-oxide-semiconductor (NMOS) transistor, the high-k metal gate layer 125 includes titanium nitride (TiN) and lanthanum (La). If the semiconductor device 100 is a p-channel metal-oxide-semiconductor (PMOS) transistor, the high-k metal gate layer 125 includes titanium nitride (TiN), lanthanum (La) and aluminum (Al). In some embodiments, the high-k metal gate layer 125 is deposited by a CVD process, a PVD process, an ALD process, a spin-on coating process, or another suitable deposition process.

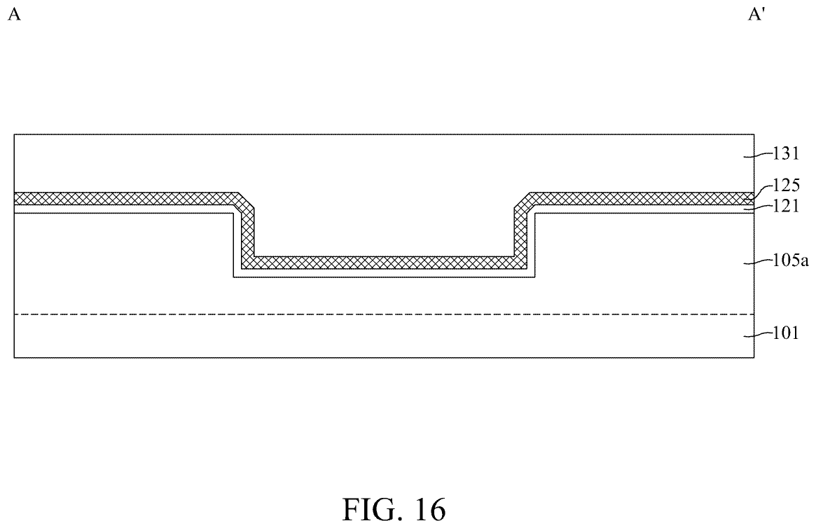

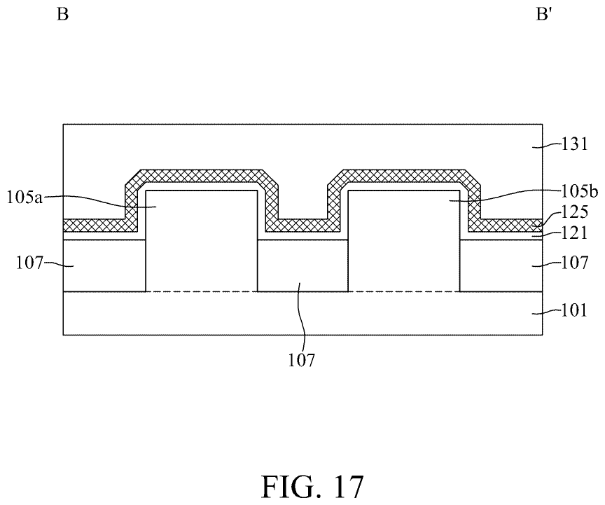

Then, a lower gate electrode layer 131 is formed over the high-k metal gate layer 125, as shown in FIGS. 16 and 17 in accordance with some embodiments. In some embodiments, the remaining portion of the recess 116 is filled by the lower gate electrode layer 131. The respective step is illustrated as the step S21 in the method 10 shown in FIG. 4.

In some embodiments, the lower gate electrode layer 131 includes polysilicon. However, other materials may also be used for the lower gate electrode layer 131. In some embodiments, the lower gate electrode layer 131 is formed by a deposition process, such as a CVD process, a PVD process, an ALD process, a spin-on coating process, or another suitable deposition process.

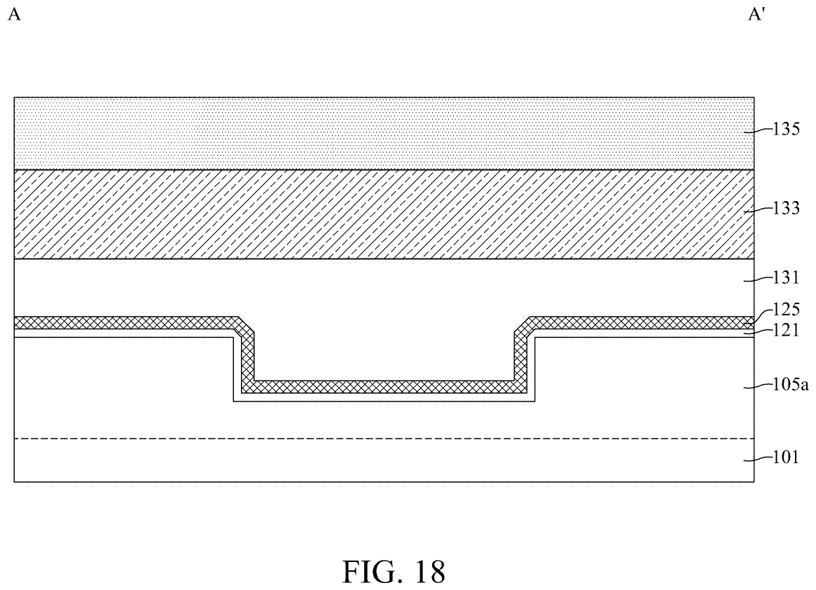

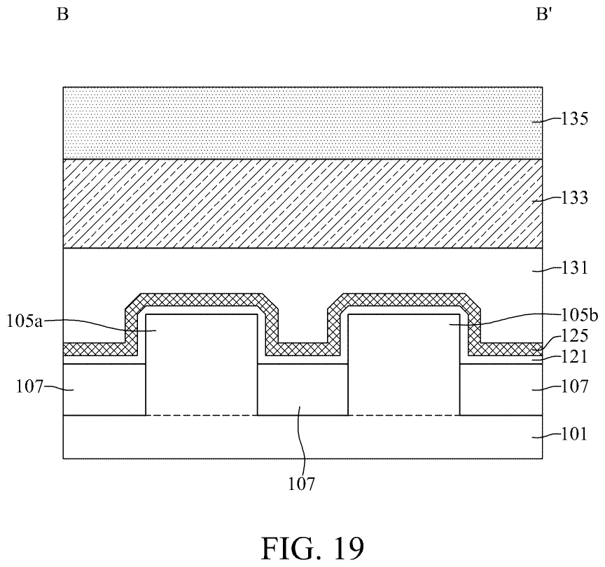

Next, an upper gate electrode layer 133 and a cap layer 135 are sequentially formed over the lower gate electrode layer 131, as shown in FIGS. 18 and 19 in accordance with some embodiments. The respective steps are illustrated as the steps S23 and S25 in the method 10 shown in FIG. 4.

In some embodiments, the upper gate electrode layer 133 includes tungsten (W). However, other materials may also be used for the upper gate electrode layer 133. In some embodiments, the cap layer 135 includes silicon nitride. However, other materials, such as silicon oxide and silicon oxynitride, may also be used for the cap layer 135. In some embodiments, the upper gate electrode layer 133 and the cap layer 135 are formed by deposition processes, such as CVD processes, PVD processes, ALD processes, spin-on coating processes, or other suitable deposition processes.

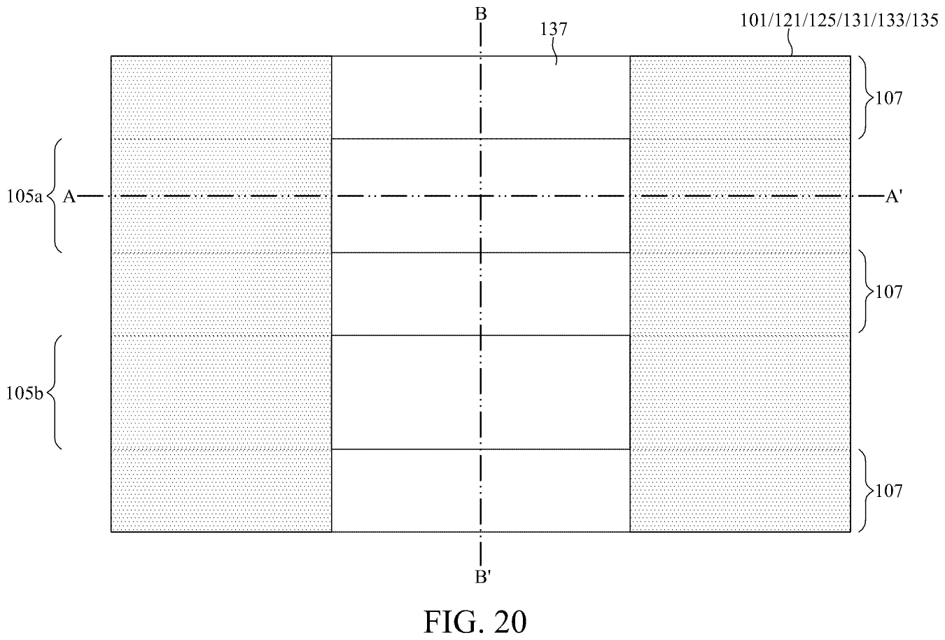

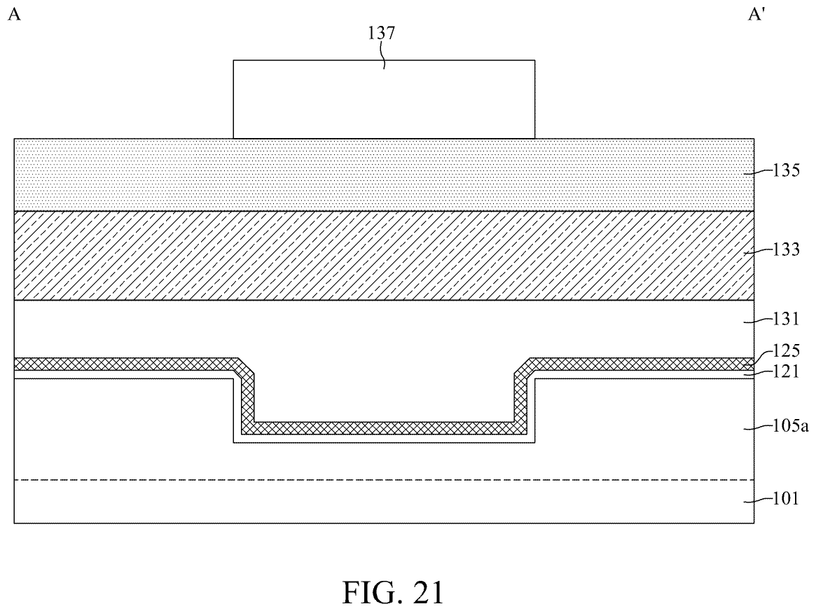

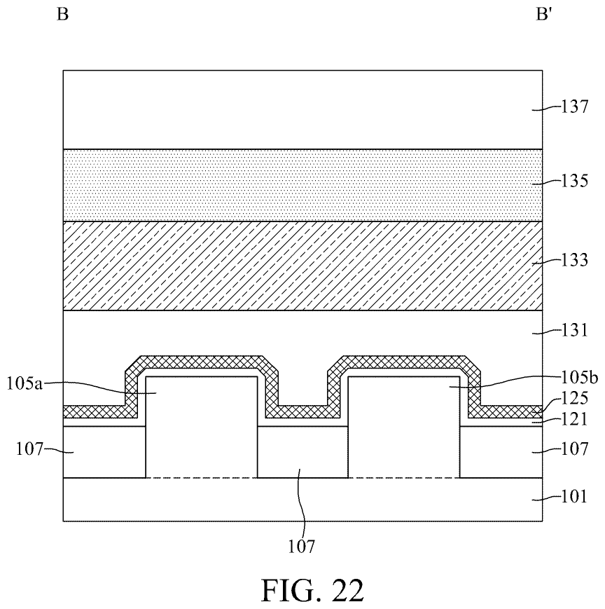

FIG. 20 is a top view illustrating an intermediate stage in the preparation of the semiconductor device 100, FIG. 21 is a cross-sectional view along the line A-A′ of FIG. 20, and FIG. 22 is a cross-sectional view along the line B-B′ of FIG. 20, in accordance with some embodiments.

After the cap layer 135 is formed, a patterned mask 137 is formed over the cap layer 135, as shown in FIGS. 20 to 22 in accordance with some embodiments. The respective step is illustrated as the step S27 in the method 10 shown in FIG. 4. In some embodiments, at least a portion of the cap layer 135 is exposed by the patterned mask 137. In some embodiments, the patterned mask 137 covers the region where a gate structure will be formed.

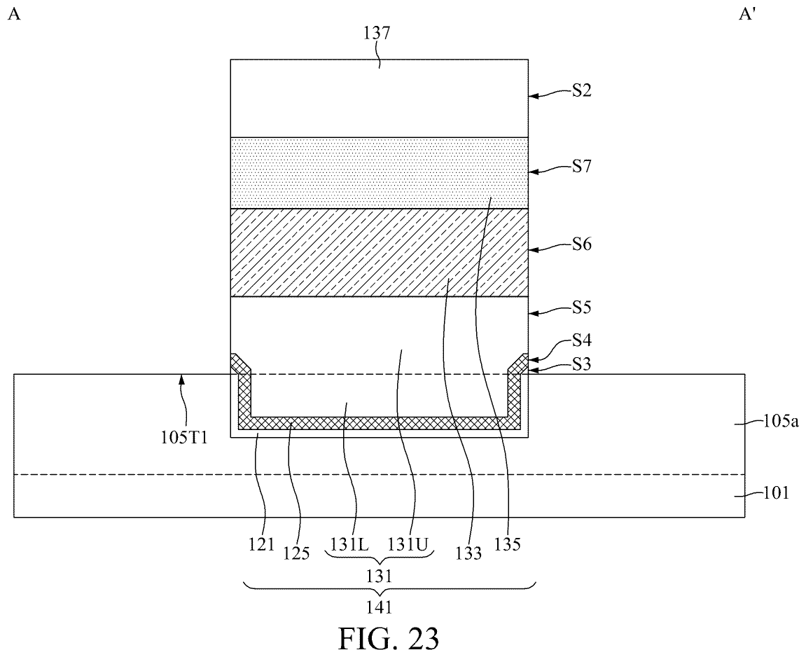

FIG. 23 is a cross-sectional view illustrating an intermediate stage following FIG. 21 in the preparation of the semiconductor device 100, along the line A-A′ of FIG. 20, in accordance with some embodiments.

As shown in FIG. 23, an etching process is performed on the gate dielectric layer 121, the high-k metal gate layer 125, the lower gate electrode layer 131, the upper gate electrode layer 133 and the cap layer 135 using the patterned mask 137 as an etching mask, in accordance with some embodiments. In some embodiments, after the etching process is performed, a gate structure 141 is formed over and extending into the fin structures 105a and 105b. The etching process may be a dry etching process or a wet etching process. The respective step is illustrated as the step S29 in the method 10 shown in FIG. 4.

In some embodiments, after the etching process is performed, a sidewall S2 of the patterned mask 137 is substantially aligned with a sidewall S3 of the gate dielectric layer 121, a sidewall S4 of the high-k metal gate layer 125, a sidewall S5 of the lower gate electrode layer 131 (i.e., the sidewall of the upper portion 131U of the lower gate electrode layer 131), a sidewall S6 of the upper gate electrode layer 133 and a sidewall S7 of the cap layer 135. The sidewalls S3, S4, S5, S6 and S7 may collectively form a sidewall of the gate structure 141. In some embodiments, each of the sidewalls S3, S4, S5, S6 and S7 is higher than the top surfaces of the fin structures 105a and 105b (e.g., the top surface 105T1 of the fin structure 105a).

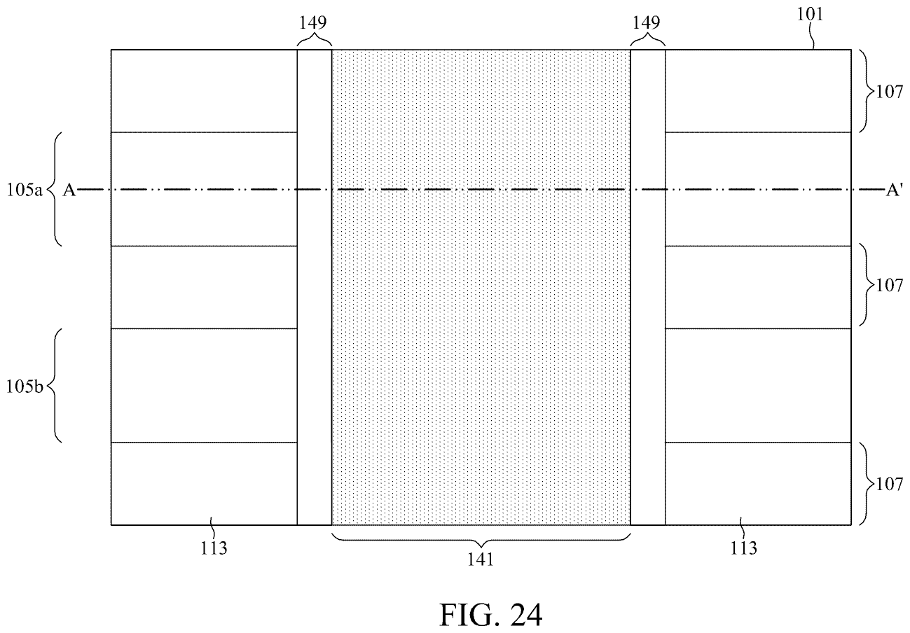

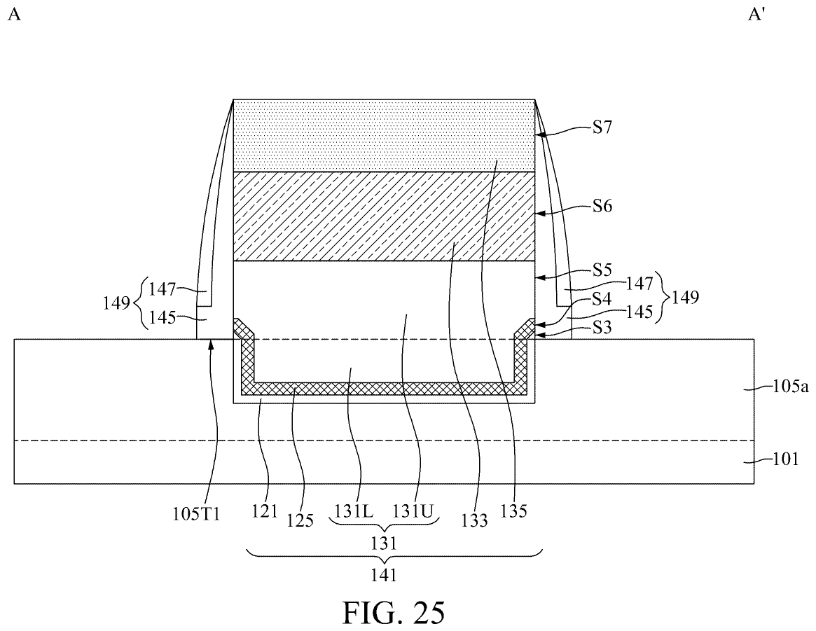

FIG. 24 is a top view illustrating an intermediate stage in the preparation of the semiconductor device 100, and FIG. 25 is a cross-sectional view along the line A-A′ of FIG. 24, in accordance with some embodiments. After the gate structure 141 is formed, a spacer structure 149 is formed to cover opposite sidewalls of the gate structure 141, as shown in FIGS. 24 and 25 in accordance with some embodiments. The respective step is illustrated as the step S31 in the method 10 shown in FIG. 4.

In some embodiments, the sidewall S3 of the gate dielectric layer 121, the sidewall S4 of the high-k metal gate layer 125, the sidewall S5 of the lower gate electrode layer 131 (i.e., the sidewall of the upper portion 131U of the lower gate electrode layer 131), the sidewall S6 of the upper gate electrode layer 133 and the sidewall S7 of the cap layer 135 are covered by and in direct contact with the spacer structure 149. In some embodiments, the spacer structure 149 is formed over and in direct contact with the top surfaces of the fin structures 105a and 105b (e.g., the top surface 105T1 of the fin structure 105a). In some embodiments, the spacer structure 149 includes a first spacer layer 145 and a second spacer layer 147 disposed over the first spacer layer 145.

The formation of the spacer structure 149 includes conformally depositing a first spacer material (not shown) over the structure of FIG. 23, followed by conformally depositing a second spacer material (not shown) over the first spacer material. Then, an etching process is performed to partially remove the first and the second spacer materials, leaving the first spacer layer 145 and the second spacer layer 147 on the sidewalls of the gate structure 141. In some embodiments, the etching process includes a dry etching process, a wet etching process, or a combination thereof. After the spacer structure 149 is formed, the fin structures 105a and 105b are partially exposed.

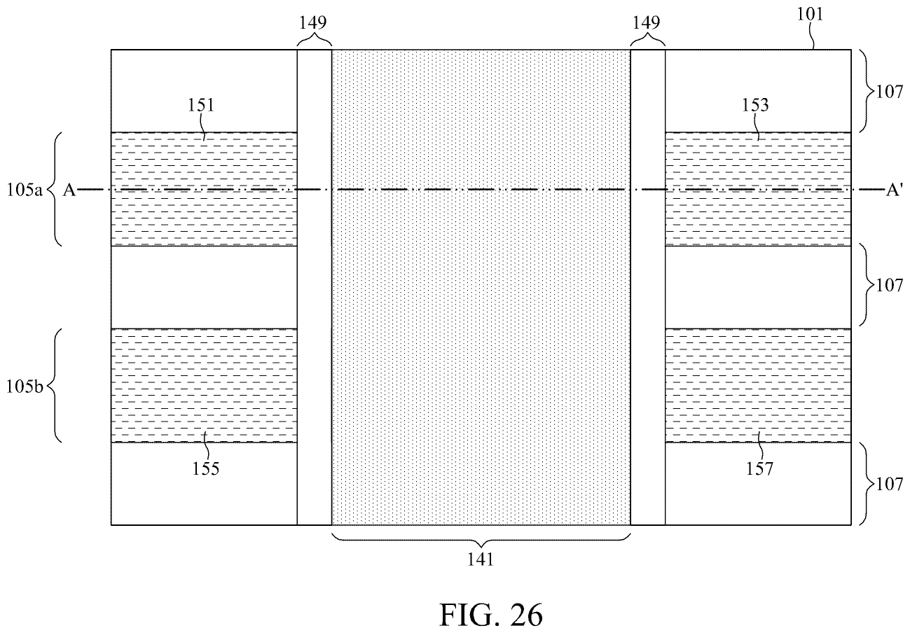

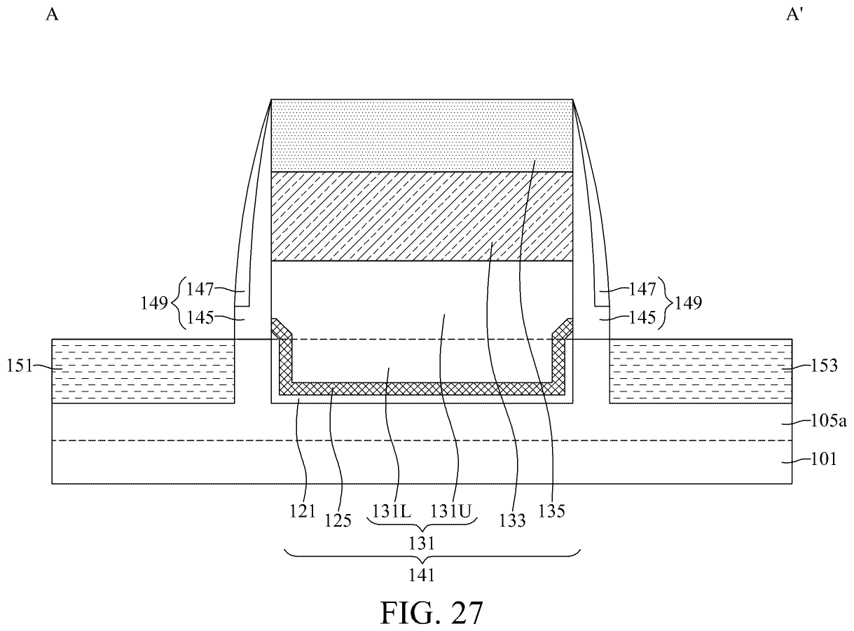

FIG. 26 is a top view illustrating an intermediate stage in the preparation of the semiconductor device 100, and FIG. 27 is a cross-sectional view along the line A-A′ of FIG. 26, in accordance with some embodiments. After the spacer structure 149 is formed, a plurality of S/D regions 151, 153, 155 and 157 are formed in the fin structures 105a and 105b, as shown in FIGS. 26 and 27 in accordance with some embodiments. The respective step is illustrated as the step S33 in the method 10 shown in FIG. 4.

In some embodiments, the S/D regions 151, 153, 155 and 157 are formed adjacent to the spacer structure 149. In some embodiments, the S/D regions 151 and 153 are disposed in the fin structure 105a and at opposite sides of the gate structure 141, and the S/D regions 155 and 157 are disposed in the fin structure 105b and at opposite sides of the gate structure 141. In some embodiments, the S/D regions 151, 153, 155 and 157 are formed by one or more ion implantation processes, and p-type dopants, such as boron (B), gallium (Ga), or indium (In), or n-type dopants, such as phosphorous (P) or arsenic (As), can be implanted in the fin structures 105a and 105b to form the S/D regions 151, 153, 155 and 157, depending on the conductivity type of the semiconductor device 100.

After the S/D regions 151, 153, 155 and 157 are formed, a dielectric layer 161 is formed to cover the S/D regions 151, 153, 155, 157 and the gate structure 141, and conductive contacts 171, 173, 175 and 177 are formed penetrating through the dielectric layer 161, as shown in FIGS. 1 to 3 in accordance with some embodiments. In some embodiments, the dielectric layer 161 may be referred to as an interlayer dielectric (ILD) layer. In some embodiments, the conductive contact 171 is formed over and electrically connected to the S/D region 151, the conductive contact 173 is formed over and electrically connected to the S/D region 153, the conductive contact 175 is formed over and electrically connected to the S/D region 155, the conductive contact 177 is formed over and electrically connected to the S/D region 157. The respective steps are illustrated as the steps S35 and S37 in the method 10 shown in FIG. 4.

In some embodiments, the dielectric layer 161 includes silicon oxide, silicon nitride, silicon oxynitride, tetraethylorthosilicate (TEOS) formed oxide, undoped silicate glass, doped silicon oxide (e.g., phosphosilicate glass (PSG), borophosphosilicate glass (BPSG), boron doped silicon glass (BSG)), a low-k dielectric material, another suitable dielectric material, or a combination thereof. The dielectric layer 161 may be formed by a deposition process, such as a CVD process, a PVD process, an ALD process, a spin-on coating process, or another suitable deposition process.

In some embodiments, the conductive contacts 171, 173, 175 and 177 include aluminum (Al), copper (Cu), tungsten (W), titanium (Ti), tantalum (Ta), a combination thereof, or another suitable conductive material. The formation of the conductive contacts 171, 173, 175 and 177 may include partially removing the dielectric layer 161 to form contact openings (not shown) by an etching process, followed by forming the conductive contacts 171, 173, 175 and 177 in the contact openings.

The conductive contacts 171, 173, 175 and 177 may be formed by a deposition process and a subsequent planarization process. The deposition process may include a CVD process, a PVD process, an ALD process, a plating process, or another suitable deposition process. The planarization process may include a chemical mechanical polishing (CMP) process.

Embodiments of the semiconductor device 100 with the high-k metal gate layer 125 and method for preparing the same are provided in the disclosure. In some embodiments, the semiconductor device 100 includes the gate structure 141 disposed over and extending into the fin structures 105a and 105b. Since the gate structure 141 includes the high-k metal gate layer 125, and the high-k metal gate layer 125 is disposed in the recess 116 in the fin structures 105a and 105b (see FIGS. 9 and 10), the gate control ability is increased, and the leakage current is reduced or eliminated. As a result, the overall performance of the semiconductor device 100 can be significantly improved.

In one embodiment of the present disclosure, a semiconductor device is provided. The semiconductor device includes a fin structure disposed over a semiconductor substrate. The semiconductor device also includes a source/drain (S/D) region disposed in the fin structure. The semiconductor device further includes a gate structure disposed over and extending into the fin structure. The gate structure is disposed adjacent to the S/D region. The gate structure includes a high-k metal gate layer and a lower gate electrode layer disposed over the high-k metal gate layer.

In another embodiment of the present disclosure, a semiconductor device is provided. The semiconductor device includes a first fin structure disposed over a semiconductor substrate and extending along a direction. The semiconductor device also includes a source/drain (S/D) region disposed in the first fin structure. The semiconductor device further includes a gate structure disposed across the first fin structure and adjacent to the S/D region. The gate structure includes a high-k metal gate layer, and a lower gate electrode layer disposed over the high-k metal gate layer. A top surface of the first fin structure is higher than a bottom surface of the gate structure in a cross section along the direction of the first fin structure.

In yet another embodiment of the present disclosure, a method for preparing a semiconductor device is provided. The method includes forming a first fin structure over a semiconductor substrate and partially removing the first fin structure to form a recess. The method also includes depositing a high-k metal gate layer lining and partially filling the recess and depositing a lower gate electrode layer over the high-k metal gate layer. A remaining portion of the recess is filled by the lower gate electrode layer. The method further includes performing an etching process on the high-k metal gate layer and the lower gate electrode layer to form a gate structure and forming a source/drain (S/D) region in the first fin structure and adjacent to the gate structure.

The embodiments of the present disclosure have some advantageous features. By forming a gate structure with a high-k metal gate layer that extends into a fin structure, the gate control ability is increased, and the leakage current is reduced or eliminated. As a result, the overall performance of the semiconductor device can be significantly improved.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, and steps.

What is claimed is:

1. A method for preparing a semiconductor device, comprising:
forming a first fin structure over a semiconductor substrate;
partially removing the first fin structure to form a recess;
depositing a high-k metal gate layer lining and partially filling the recess;
depositing a lower gate electrode layer over the high-k metal gate layer, wherein a remaining portion of the recess is filled by the lower gate electrode layer;
performing an etching process on the high-k metal gate layer and the lower gate electrode layer to form a gate structure; and
forming a source/drain (S/D) region in the first fin structure and adjacent to the gate structure.

2. The method for preparing a semiconductor device of claim 1, further comprising:
forming an isolation structure over the semiconductor substrate, wherein the first fin structure protrudes from the isolation structure, and a bottom surface of the recess is higher than a top surface of the isolation structure.

3. The method for preparing a semiconductor device of claim 1, further comprising:
forming a second fin structure over the semiconductor substrate, wherein the second fin structure extends parallel to the first fin structure, and the second fin structure is partially removed to form the recess.

4. The method for preparing a semiconductor device of claim 1, further comprising:
depositing a gate dielectric layer covering a sidewall and a bottom surface of the recess in the first fin structure before the high-k metal gate layer is formed.

5. The method for preparing a semiconductor device of claim 4, wherein the gate dielectric layer is partially removed by the etching process to form the gate structure, such that a sidewall of the gate dielectric layer is substantially aligned with a sidewall of the high-k metal gate layer.

6. The method for preparing a semiconductor device of claim 1, wherein the high-k metal gate layer is separated from the sidewall and the bottom surface of the recess in the first fin structure by the gate dielectric layer.

7. The method for preparing a semiconductor device of claim 1, wherein before performing the etching process, the method further comprises:
depositing an upper gate electrode layer over the lower gate electrode layer; and
depositing a cap layer over the upper gate electrode layer.

8. The method for preparing a semiconductor device of claim 7, further comprising:
forming a patterned mask over the cap layer, wherein the gate structure is formed by performing the etching process on the gate dielectric layer, the high-k metal gate layer, the upper gate electrode layer and the cap layer using the patterned mask as a mask.

9. The method for preparing a semiconductor device of claim 1, wherein a top surface of the first fin structure is exposed after the etching process is performed.

10. The method for preparing a semiconductor device of claim 9, further comprising:
forming a spacer structure covering a sidewall of the gate structure, wherein the spacer structure is in direct contact with the top surface of the first fin structure.

11. The method for preparing a semiconductor device of claim 10, wherein the S/D region is formed after the spacer structure is formed.
